(19) United States
(12) Patent Application Publication
(10) Pub. No.: US 2017/0201083 A1
(43) Pub. Date: Jul. 13, 2017

(54) Power Converter Provided with Dual Function Bus Bars

(71) Applicant: TM4 INC., Boucherville (CA)

(72) Inventors: Mohammed AMAR, Montreal (CA); Benoit BLANCHART ST-JACQUES, McMasterville (CA)

(73) Assignee: TM4 INC., Boucherville (CA)

(21) Appl. No.: 15/316,438

(22) PCT Filed: Jun. 2, 2015
(86) PCT No.: PCT/CA2015/050511

§ 371 Date: Dec. 6, 2016

Related U.S. Application Data
(60) Provisional application No. 62/008,590, filed on Jun. 6, 2014.

(51) Int. Cl. H02G 5/10; H02M 7/00; H02M 7/537; H05K 7/20

(52) U.S. Cl. CPC H02G 5/10; H05K 7/2089; H02M 7/003; H02M 7/537

(57) ABSTRACT

A power converter includes bus bars that have a dual function of cooling the electronic switches and of conducting power to or from the electronic switches. Indeed, the electronic switches, that are packaged in a TO-220 or similar package, have the large tab of the package directly soldered or otherwise fastened to the bus bar, therefore efficiently cooling the switches. Furthermore, since the tabs are electrically connected to a portion of the electronic switch, the bus bars are connected to a portion of the electronic circuit of the power converter.

### FIELD

The present disclosure relates to power converters. More specifically, the present disclosure is concerned with power converters provided with dual function bus bars.

### BACKGROUND

Power converters are well known in the art. For example, they are often used to convert a DC voltage into an AC voltage. Such converters often provide a multiphase output, for example, three-phase inverters are often seen.

Electronically controlled switches are often used to convert the DC voltage into the AC voltage through precise control of the opening and closing of the electronically controlled switches.

When high-powered power converters are required, the designer may use high power switches or use many low power switches connected in parallel. This second choice is often cost effective.

### BRIEF DESCRIPTION OF THE DRAWINGS

In the appended drawings:

FIG. 1 is a schematic view of a H-bridge three-phase power converter using parallelized Mosfets;

FIG. 2 is a perspective view of a dual function bus bar according to an illustrative embodiment;

FIG. 3 is a perspective view of a three-phase power converter using parallelized Mosfets mounted to six dual function bus bars of FIG. 2;

FIG. 4 is a perspective view of the power converter of FIG. 3; and

FIG. 5 is a sectional view of the power converter of FIG. 3.

### DETAILED DESCRIPTION

According to an illustrative embodiment, there is provided a power converter including a casing provided with a cooling arrangement, an electronic circuit, at least two electronic switches provided in packages that include a tab electrically connected to a portion of the electronic circuit and a dual function bus bar to which the tab of each at least two electronic switches is mounted; the bus bar being electrically connected to the electronic circuit and mechanically connected to the cooling arrangement.

The use of the word “a” or “an” when used in conjunction with the term “comprising” in the claims and/or the specification may mean “one”, but it is also consistent with the meaning of “one or more”, “at least one”, and “one or more than one”. Similarly, the word “another” may mean at least a second or more.

As used in this specification and claim(s), the words “comprising” (and any form of comprising, such as “comprise” and “comprises”), “having” (and any form of having, such as “have” and “has”), “including” (and any form of including, such as “include” and “includes”) or “containing” (and any form of containing, such as “contain” and “contains”), are inclusive or open-ended and do not exclude additional, unrecited elements or process steps.

In the present specification and in the appended claims, various terminology which is directional, geometrical and/or spatial in nature such as “longitudinal”, “horizontal”, “front”, rear”, “upwardly”, “downwardly”, etc. is used. It is to be understood that such terminology is used for ease of description and in a relative sense only and is not to be taken in any way as a limitation upon the scope of the present disclosure.

The expression “connected” should be construed herein and in the appended claims broadly so as to include any cooperative or passive association between mechanical parts or components. For example, such parts may be connected together by direct coupling, or indirectly connected using further parts therebetween. The connection can also be remote, using for example a magnetic field or else.

Other objects, advantages and features of the present power converter provided with dual function bus bars will become more apparent upon reading of the following non-restrictive description of illustrative embodiments thereof, given by way of example only with reference to the accompanying drawings.

Generally stated, the power converter described herein includes bus bars that have a dual function of cooling the electronic switches and of conducting power to or from the electronic switches. Indeed, the electronic switches, that are, in the illustrative embodiment, Mosfet switches packaged in a TO-220 or similar package, have the large tab of the package directly soldered or otherwise fastened to the bus bar, therefore efficiently cooling the Mosfet switches. Furthermore, since the tabs are electrically connected to the drain of the Mosfet switches, each of the bus bars interconnecting the parallelized top switches are connected to the positive terminal of the power source while each of the bus bars interconnecting the parallelized bottom switches become one of the three phase terminals.

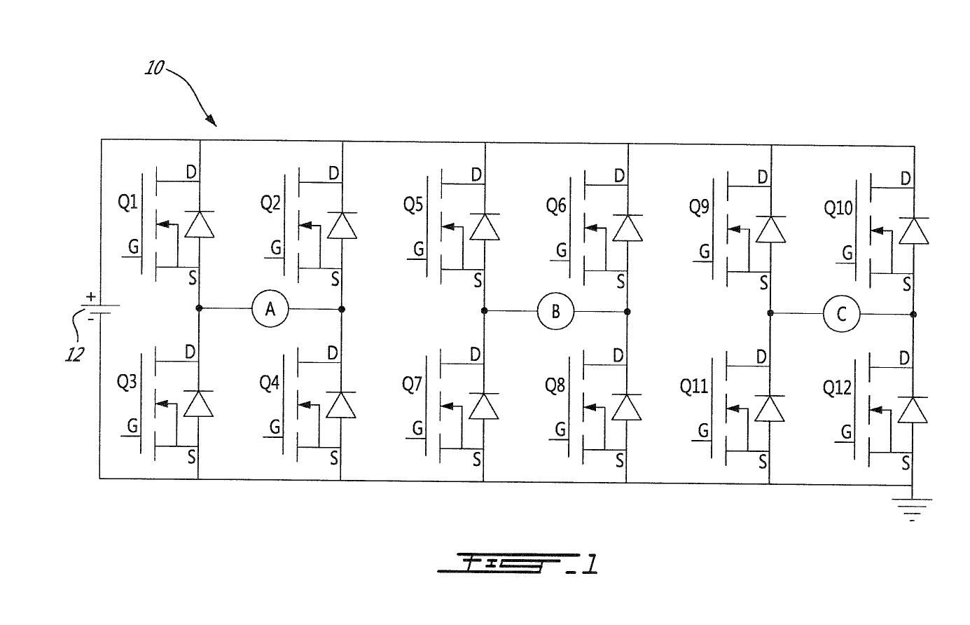

FIG. 1 schematically illustrates a power converter 10 using parallelized electronically controlled switches. More specifically, FIG. 1 illustrates a three-phase H-bridge power converter where two switches are parallelized for each switch position. Indeed, the twelve switches Q1-Q12 are interconnected in switch pairs Q1, Q2; Q3, Q4; Q5, Q6; Q7, Q8; Q9, Q10; and Q11, Q12. The drain connection D of switches Q1, Q2, Q5, Q6, Q9 and Q10 are interconnected and connected to the positive side of the power source 12. The drain of switch-pairs Q3, Q4; Q7, Q8 and Q11, Q12 are interconnected and respectively define the phase outputs A, B and C of the converter 10.

One skilled in the art will understand that while two switches are shown for each switch position in FIG. 1, more than two switches could be used.

Of course, many elements required for the operation of the power converter 10 have been omitted for concision purpose.

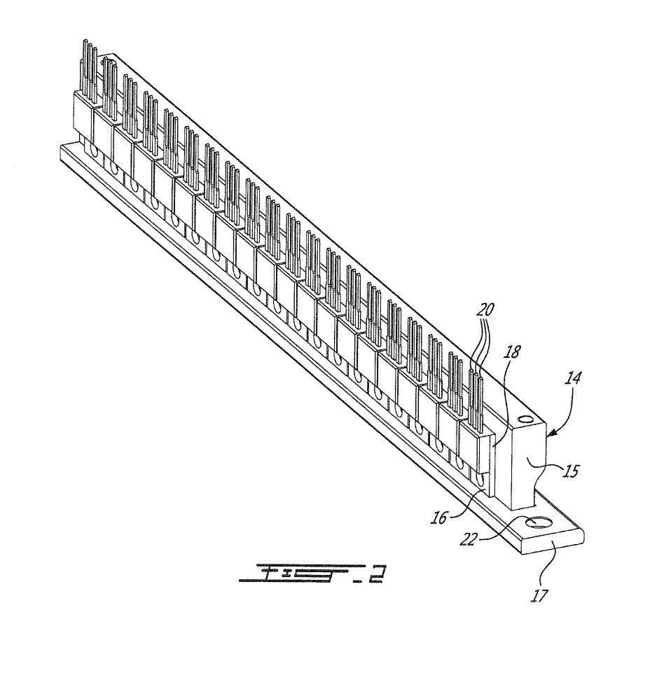

FIG. 2 illustrates, in a perspective view, a double function bus bar 14 according to an illustrative embodiment. As can be seen from this figure, the bus bar 14 has an inverted T-shape. The vertical portion 15 of the bus bar 14 is intended to receive switches 16 thereunto. The switches have a tab 18 and three leads 20. The tabs 18, which are conventionally connected to the drain D of the Mosfet switch, are parallelized since they are electrically and mechanically connected to the metallic bus bar 14, which is conventionally made of copper. The connection between the tabs 18 and the vertical portion 15 of the bus bar 14 is made via a soldering process that provides a good electrical and mechanical contact between these two parts to allow efficient current and heat conduction therebetween.

As will be easily understood from the foregoing description, the horizontal portion 17 of the bus bar 14 is intended to be connected to a cooling assembly for efficient heat transfer while being electrically insulated therefrom. The horizontal portion 17 also includes an aperture 22 allowing the bus bar 14 to be electrically connected to the positive terminal of the power supply or to be used as the phase outputs A, B and C of the converter. In other words, the bus bar 14 is electrically connected to a portion of the electronic circuit of the power inverter.

As can be seen from FIG. 2, twenty (20) electronically controlled switches 16 are parallelized.

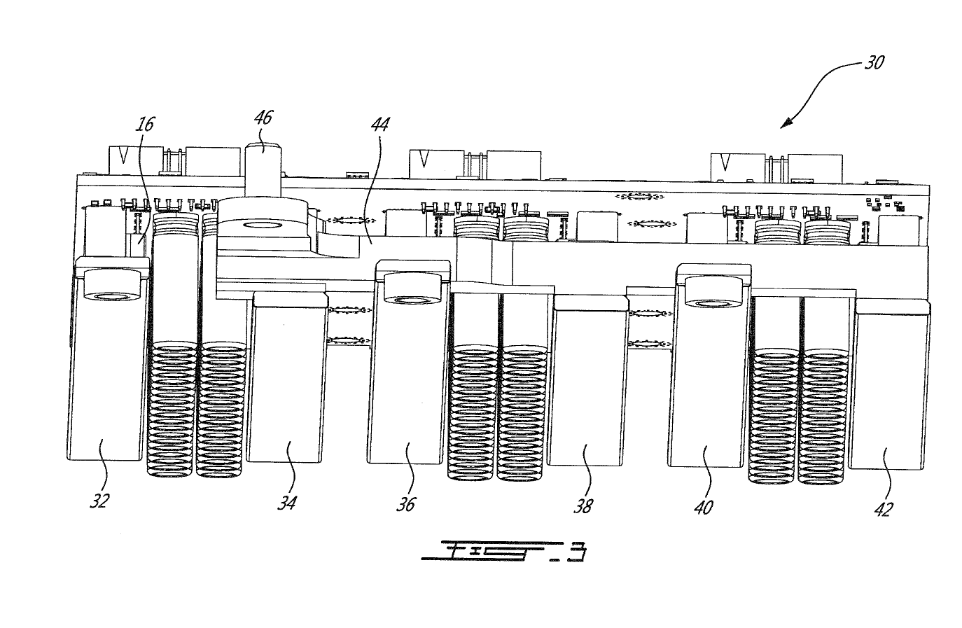

FIGS. 3 to 5 of the appended drawings illustrate a three-phase power converter 30 using six dual function bus bars such as 14 as illustrated in FIG. 2 to define a three-phase H-bridge power converter. Since these converters are believed well known to those skilled in the art, only the interconnection of the bus bars will be described herein, for concision purpose.

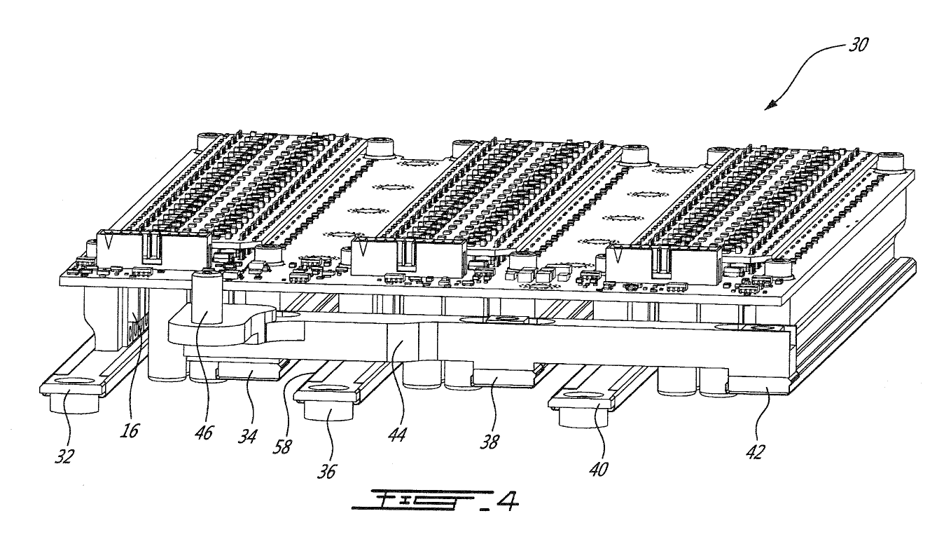

Six dual function bus bars 32-42 are used in the power converter 30. As can be better seen from FIG. 4, the bus bars 32, 36 and 40 define the phase outputs while the bus bars 34, 38 and 42 are interconnected and define the connection point for the positive side of the power source (not shown). Indeed, a bracket 44 is used to electrically interconnect the bus bars 34, 38 and 42 and provide a single connection point 46.

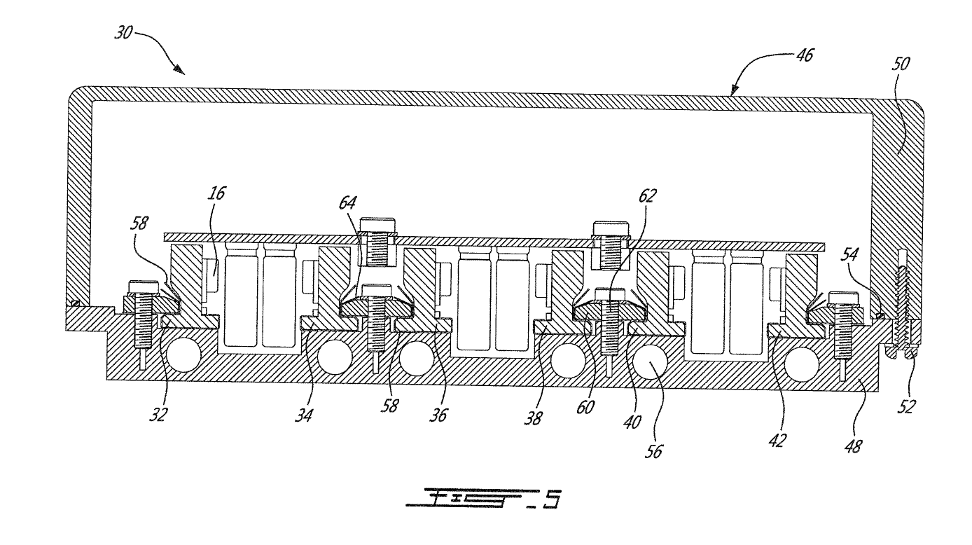

Turning now to FIG. 5, the power converter 30 include a casing 46 including a cooling assembly 48 defining the base thereof and a cover 50 mounted to the cooling assembly via fasteners 52 (only one shown). An O-ring 54 seals the interface between the cover 50 and the base 48. The cooling assembly 48 includes tubing 56 embedded or otherwise formed therein to allow cooling fluid (not shown) to flow therethrough, for example by the action of a pump (not shown), to thereby cool the power converter 30.

A thin layer of electrically insulating material 58 is interposed between the horizontal portions of the bus bars 32-42 and the cooling assembly 48 to keep these elements electrically insulated while allowing the cooling of the bus bars 32-42. For example, the electrically insulating material could combine a thin insulating material layer with a filled silicon rubber.

To ensure an adequate mechanical contact between the bus bars 32-42 and the cooling assembly 48, longitudinal pressure-applying elements 60 are fastened to the cooling assembly 48 via a plurality of fasteners 62. In other words, the horizontal portion 17 is mechanically connected to the cooling arrangement via the pressure-applying element, which applies a biasing force onto the horizontal portion 17 towards the cooling arrangement.

To further ensure electrical insulation, another thin layer of insulating material 64 is provided between the elements 60 and the bus bars.

One skilled in the art will understand that the electrically controlled switches 16 can be welded to the bus bar via a reflow soldering process. Of course, critical temperatures at which the switches 16 can be damaged should be avoided. In other words, an adequate soldering profile is used to avoid damaging the Mosfets during the soldering process.

One skilled in the art will understand that by soldering the switches to the dual-function bus bar, the lifespan of the switches is increased since the capacity for thermal cycling is increased by the increased thermal dissipation. Furthermore, the increased thermal dissipation allows a performance improvement of the switches. For example, since the soldered bus bar can be viewed as an extension of the tabs of the switches, the thermal inertia of the tabs is increased, which, in turn, increases the transitory performances of the switches.

Furthermore, since the temperature of the soldered switches is more uniform, the reliability of the power converter is increase since the likelihood of one switch failing since it cycles to higher temperatures is decreased. The similarity between the Coefficient of Thermal Expansion (CTE) of the copper bus bar, the solder joint and the tabs of the switches improves the thermal cycling capability of the assembly since it decreases the mechanical stress produced by the inherent thermal dilatation.

One skilled in the art will also understand that the soldering of the switches onto the bus bars reduces the manufacturing costs since the process can be automated.

As will easily be understood by one skilled in the art, even though the individual Mosfet switches are described hereinabove as being packaged in a TO-220 style package, other packages having a tab that can be soldered and that is electrically connected to one of the drain and source terminal of the switch could be used.

Similarly, other types of electronic switches that are so packaged could be used.

While the bus bar 14 is described as being made of copper, other heat and current conducting materials or alloys could be used.

As will easily be understood by one skilled in the art, while a H-bridge three-phase power converted has been described herein, other types of power converters could benefit from a dual-function bus bar.

One skilled in the art will also understand that since the dual function bus bar is electrically connected to the tabs of the switches, the PCBs of the power converters sees less power transit therethrough which allows the use of a thinner copper layer in the PCB and provides a generally cooler PCB. Indeed, since less power transits via the PCB, the PCB remains cooler and the capacitors are therefore easier to cool to thereby increase their lifespan.

It is to be understood that the power converter provided with dual function bus bars is not limited in its application to the details of construction and parts illustrated in the accompanying drawings and described hereinabove. The power converter provided with dual function bus bars is capable of other embodiments and of being practiced in various ways. It is also to be understood that the phraseology or terminology used herein is for the purpose of description and not limitation. Hence, although the power converter provided with dual function bus bars has been described hereinabove by way of illustrative embodiments thereof, it can be modified, without departing from the spirit, scope and nature of the subject invention.

What is claimed is:

1. A power converter including:
a casing provided with a cooling arrangement;
an electronic circuit;
at least two electronic switches provided in packages that include a tab electrically connected to a portion of the electronic circuit; and
a dual function bus bar to which the tab of each at least two electronic switches is mounted; the bus bar being electrically connected to the electronic circuit and mechanically connected to the cooling arrangement.

2. A power converter as recited in claim 1, wherein the dual function bus bar has a generally inverted T-shape.

3. A power converter as recited in claim 2, wherein a vertical portion of the bus bar receives the tab of the electronic switches and wherein a horizontal portion of the bus bar is mechanically connected to the cooling arrangement.

4. A power converter as recited in claim 3, wherein the horizontal portion is mechanically connected to the cooling arrangement via an element applying a biasing force onto the horizontal portion towards the cooling arrangement.

5. A power converter as recited in claim 3, further comprising an electrical insulating layer provided between the bus bar and the cooling arrangement.

6. A power converter as recited in claim 4, further comprising an electrical insulating layer provided between the biasing force applying element and the bus bar.

7. A power converter as recited in claim 1, wherein the bus bar is electronically connected to the electronic circuit of the switches via a soldering of the tab of each of the at least two electronic switches to the bus bar.

8. A power converter as recited in claim 1, wherein the cooling arrangement of the casing is so configured that a cooling channel is provided in the vicinity of the mechanical connection of the bus bar to the cooling arrangement.

9. A dual function bus bar to mechanically and electrically interconnect at least two electronic switches in parallel, the bus bar including a first surface onto which an electrically conductive portion of the at least two electronic switches in mounted and a second surface so configured as to be applied to a cooling arrangement.

10. A dual function bus bar as recited in claim 9, wherein the bus bar has a generally inverted T-shape; a vertical portion of the bus bar including the first surface while a horizontal portion of the bus bar including the second surface.

11. A power converter as recited in claim 10, wherein the at least two electronic switches are provided with a tab that is electrically connected to a portion of the electronic switch, and wherein a vertical portion of the bus bar receives the tab of the electronic switches and wherein a horizontal portion of the bus bar is mechanically connected to the cooling arrangement.

12. A power converter as recited in claim 10, wherein the horizontal portion is mechanically connected to the cooling arrangement via an element applying a biasing force onto the horizontal portion towards the cooling arrangement.

13. A power converter as recited in claim 10, further comprising an electrical insulating layer provided between the bus bar and the cooling arrangement.

14. A power converter as recited in claim 12, further comprising an electrical insulating layer provided between the biasing force applying element and the bus bar.

15. A power converter as recited in claim 11, wherein the bus bar is electronically connected to the electronic circuit of the switches via a soldering of the tab of each of the at least two electronic switches to the bus bar.
